(19) United States
(12) Patent Application Publication
(10) Pub. No.: US 2025/0210103 A1
(43) Pub. Date: Jun. 26, 2025

(54) MEMORY DEVICE PERFORMING IN-MEMORY COMPUTING AND OPERATING METHOD THEREOF

(71) Applicant: SEOUL NATIONAL UNIVERSITY R&DB FOUNDATION, Seoul (KR)

(72) Inventors: Jae-Joon KIM, Seoul (KR); Eunhwan KIM, Pohang-si (KR)

(21) Appl. No.: 18/976,468

(22) Filed: Dec. 11, 2024

(30) Foreign Application Priority Data
Dec. 20, 2023 (KR) 10-2023-0187030
Apr. 19, 2024 (KR) 10-2024-0052558

(51) Int. Cl. G11C 11/412; G11C 5/06; G11C 11/419

(52) U.S. Cl. CPC G11C 11/412; G11C 5/063; G11C 11/419

(57) ABSTRACT

A memory device includes a plurality of memory cells; a plurality of bit lines respectively connected to the plurality of memory cells; a plurality of separation switches, each being arranged in a central separation region of each bit line for each bit line and separating the central separation region of each bit line in response to a separation signal or connecting separated central separation regions to each other in response to the separation signal; a plurality of sharing switches, each being arranged between adjacent bit lines and separating the adjacent bit lines from each other or connecting the adjacent bit lines to each other in response to a charge sharing signal; and at least one ground switch connected to one end portion of each bit line for each bit line and selectively grounding each bit line.

### CROSS-REFERENCE TO RELATED APPLICATION

This application claims the benefit under 35 USC 119(a) of Korean Patent Application Nos. 10-2024-0052558 filed on Apr. 19, 2024 and 10-2023-0187030 filed on Dec. 20, 2023 in the Korean Intellectual Property Office, the entire disclosures of which are incorporated herein by reference for all purposes.

### BACKGROUND

### 1. Field

The present disclosure relates to a memory device performing in-memory computing and an operating method thereof.

### 2. Description of the Related Art

Computing in memory (CIM) is also called in-memory computing (IMC) or processing in memory (PIM) and is technology that enables a memory to perform operational functions in addition to data storage functions and has been widely studied recently as technology for implementing artificial intelligence (AI) semiconductors.

Meanwhile, such a memory device includes a plurality of memory cells arranged in an array form, and bit lines are respectively connected to the plurality of memory cells to accumulate outputs of the plurality of memory cells and transmit the outputs to a final output terminal.

FIGS. 1A, 1B, and 1C respectively illustrate structures of bit lines in a memory device that performs the general in-memory computing.

As illustrated in FIGS. 1A to 1C, each of the conventional circuits requires an additional capacitor in a process of adjusting importance of each bit line BL_{c}, shifting output values of respective bit lines, and summing the outputs, and thus, there is a problem in that an area of the circuit increases.

For example, as illustrated in FIG. 1A, the importance may be adjusted for each bit line by connecting capacitors differently for each bit line. That is, the capacitors are connected in such a way that a half of capacitance is applied to the first bit line from the left, a quarter of capacitance is applied to the second bit line, and one eighth of capacitance is applied to the third bit line.

In addition, as illustrated in FIG. 1B, a configuration is known in which capacitors of the same capacity are connected to each other for each bit line, but the capacitors of each bit line are selectively connected through a switching element.

In addition, as illustrated in FIG. 1C, a method is known in which capacitors of the same capacity are connected to each other for each bit line, but adjacent bit lines are selectively connected through a switching element, and electric charges are shared between the capacitors.

The present disclosure proposes a memory device that reduces an additional area by building, in each memory, a circuit for performing a process of adjusting the importance for each bit line and moving and summing outputs of the bit lines.

A related patent document includes Korean Patent Publication No. 2023-0078218 (Title of the invention: Memory device having local computing cell based on computing-in-memory).

### SUMMARY

The present disclosure provides a memory device including a built-in circuit that may perform an operation of adjusting the importance of each bit line within a memory cell and an operating method of the memory device.

However, technical problems to be achieved by the present embodiment are not limited to the technical problems described above, and there may be other technical problems.

According to an aspect of the present disclosure, a memory device includes a plurality of memory cells; a plurality of bit lines respectively connected to the plurality of memory cells; a plurality of separation switches, each being arranged in a central separation region of each of the plurality of bit lines for each bit line and separating the central separation region of each of the plurality of bit lines in response to a separation signal or connecting separated central separation regions to each other in response to the separation signal; a plurality of sharing switches, each being arranged between adjacent bit lines and separating the adjacent bit lines from each other or connecting the adjacent bit lines to each other in response to a charge sharing signal; and at least one ground switch connected to one end portion of each of the plurality of bit lines for each bit line and selectively grounding each of the plurality of bit lines.

According to another aspect of the present disclosure, an operating method of a memory device that sets importance of each bit line and includes a plurality of memory cells and a plurality of bit lines respectively connected to the plurality of memory cells is provided. The operating method includes charging capacitors of the plurality of bit lines with output values of the plurality of memory cell, within a bit line group including a predetermined number of bit lines; partially discharging electric charges charged in a capacitor of a first bit line in the bit line group; and sharing the electric charges charged in the capacitor of the first bit line which is partially discharged and electric charges charged in a capacitor of a second bit line by sharing electric charges in the capacitor of the first bit line and the capacitor of the second bit line which are adjacent to each other.

According to the present disclosure, importances of bit lines through which an output of each memory cell is transmitted may be set differently, and shift and movement operations for moving values may be performed by a memory cell array, and thus, an area of the memory device performing in-memory computing may be reduced, and energy consumption of the memory device may also be reduced.

### BRIEF DESCRIPTION OF THE DRAWINGS

FIGS. 1A, 1B, and IC respectively illustrate memory devices performing the general in-memory computing.

FIG. 2 illustrates a memory device according to an embodiment of the present disclosure.

FIG. 3 illustrates a detailed configuration of a memory cell according to an embodiment of the present disclosure.

FIG. 4 illustrates a circuit serving as a shift adder and analog-to-digital converter (ADC) among components of a memory device according to an embodiment of the present disclosure.

FIG. 5 is a waveform diagram illustrating a method of setting bit line importance of a memory device, according to an embodiment of the present disclosure.

FIG. 6 illustrates a configuration, in which a plurality of memory cells are combined with each other, according to an embodiment of the present disclosure.

FIGS. 7, 8, 9 and 10 illustrate operations of a memory cell according to an embodiment of the present disclosure.

FIG. 11 is a flowchart illustrating an operating method of a memory cell in a memory device according to an embodiment of the present disclosure.

FIG. 12 is a flowchart illustrating a method of setting bit line importance of a memory device according to an embodiment of the present disclosure.

### DETAILED DESCRIPTION

Hereinafter, embodiments of the present disclosure will be described in detail with reference to the attached drawings such that those skilled in the art to which the present disclosure belongs may easily practice the present disclosure. However, the present disclosure may be implemented in various different forms and is not limited to the embodiments described herein. In addition, in order to clearly describe the present disclosure in the drawings, parts that are not related to the description are omitted, and similar components are given similar reference numerals throughout the specification.

In the entire specification of the present disclosure, when a component is described to be “connected” to another component, this includes not only a case where the component is “directly connected” to another component but also a case where the component is “electrically connected” to another component with another element therebetween. In addition, when it is described that a portion “includes” a certain component, this means that the portion may further include another component without excluding another component unless otherwise stated.

In the present disclosure, a “portion” includes a unit realized by hardware, a unit realized by software, and a unit realized by using both. In addition, one unit may be realized by using two or more pieces of hardware, and two or more units may be realized by using one piece of hardware. Meanwhile, a “˜ portion” is not limited to software or hardware, and a “˜ portion” may be configured to be included in an addressable storage medium or may be configured to reproduce one or more processors. Therefore, in one example, “˜ portion” refers to components, such as software components, object-oriented software components, class components, and task components, and includes processes, functions, properties, and procedures, subroutines, segments of program code, drivers, firmware, microcode, circuits, data, databases, data structures, tables, arrays, and variables. The functions provided within the components and “portions” may be combined into a smaller number of components and “portions” or may be further separated into additional components and “portions”. Additionally, components and “portions” may be implemented to regenerate one or more central processing units (CPUs) included in a device or security multimedia card.

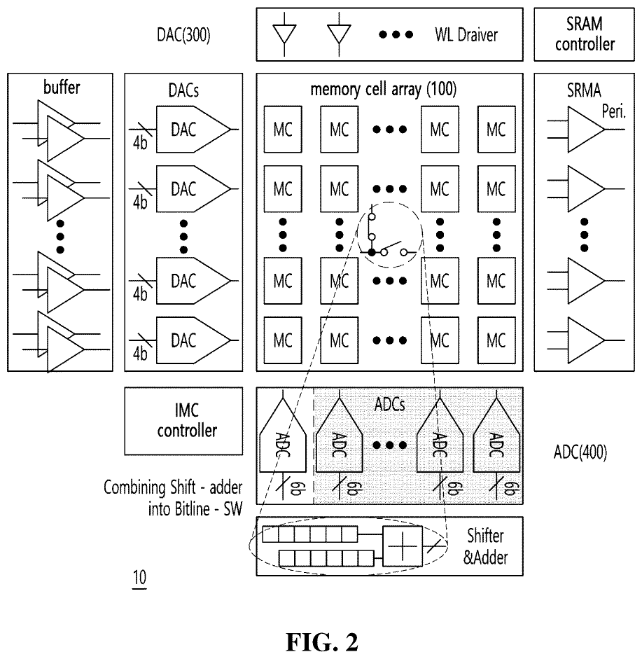

FIG. 2 illustrates a memory device according to one embodiment of the present disclosure.

The memory device 10 includes a memory cell array 100 in which a plurality of memory cells performing in-memory computing are arranged in an array form, a digital-to-analog converter (DAC) 300 that converts input data received from a buffer into an analog signal and provides the analog signal to a memory cell MC, and an analog-to-digital converter (ADC) 400 that receives the analog signal output from the memory cell array 100 and converts the analog signal into a digital signal. At this time, the DAC (300) may be implemented in a form built into a memory cell as described below. In addition, the ADC 400 may also be implemented in a form built into the memory cell array 100, and only a minimum number of ADCs are arranged outside the memory cell array 100. In addition, a shift & adder that is coupled to a peripheral circuit of the memory device 10 in the related art may also be implemented in a form built into the memory cell array 100 according to the present disclosure.

In addition, the memory device 10 may further include peripheral circuits, such as a static random access memory (SRAM) controller that controls an operation of SRAM included in each memory cell, and an in-memory computing (IMC) controller that controls the operation of each memory cell MC that performs the IMC. In this case, the input data may be input activation data of each layer constituting a deep neural network or so on, and multiplication of the input data and storage data may correspond to multiplication of an input activation and weight data.

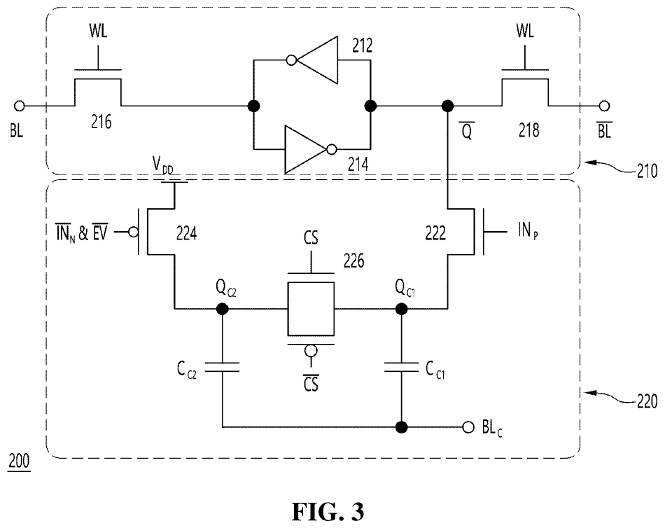

FIG. 3 illustrates a detailed configuration of a memory cell 200 according to an embodiment of the present disclosure.

The memory cell 200 of the present disclosure includes a storage unit 210 that stores storage data and an operation circuit 220. The operation circuit 220 includes a first capacitor C_{C1} and a second capacitor C_{C2}, and adjusts a voltage charged to the first capacitor C_{C1} or the second capacitor C_{C2} according to the input data and storage data. In addition, the operation circuit 220 converts the input data into an analog voltage and multiplies the storage data stored in the storage unit 210 by the input data. In addition, multiplication operation results of the memory cells 200 are sequentially accumulated and added, and accordingly, a multiplication accumulation operation may be performed. In addition, the operation circuit 220 includes the first capacitor C_{C1} and the second capacitor C_{C2} that share a charge capacity according to a charge sharing signal as a DAC that converts multi-bit input data into an analog voltage.

The storage unit 210 operates according to an SRAM structure and includes a first inverter 212, a second inverter 214, a first switching element 216, and a second switching element 218. The storage data stored in the storage unit 210 is transmitted to the operation circuit 220. In this case, the storage data may be weight data constituting an artificial intelligence model or a deep neural network model of which learning is completed.

An output terminal of the first inverter 212 is connected to an input terminal of the second inverter 214, and an output terminal of the second inverter 214 is connected to an input terminal of the first inverter 212. Because each the first and second inverters 212 and 214 includes two switching elements, the storage unit 210 includes a total of six switching elements. The first switching element 216 has one terminal connected to a connection node between the output terminal of the first inverter 212 and the input terminal of the second inverter 214, and has the other terminal connected to a bit line BL, and has a gate to which a word line signal is applied, thereby being switched according to the word line signal. The second switching element 218 has one terminal connected to a connection node /Q between the input terminal of the first inverter 212 and the output terminal of the second inverter 214, and has the other terminal connected to a bit line /BL, and has a gate to which a word line signal is applied, thereby being switched according to the word line signal. In particular, a value of the connection node /Q, to which the second switching element 218, an input terminal of the first inverter 212, and the output terminal of the second inverter 214 are connected, is transmitted to the operation circuit 220. In this case, the connection node /Q functions as an output node from which the storage unit 210 outputs the stored data.

The operation circuit 220 causes a third switching element 226 to selectively connect one terminal of the first capacitor C_{C1} to one terminal of the second capacitor C_{C2}, and causes the other terminal of the first capacitor C_{C1} and the other terminal of the second capacitor C_{C2} to an output terminal BL. In addition, the first capacitor C_{C1} and the second capacitor C_{C2} are precharged to a high voltage, and when high-level input data is input, a charging state of the first capacitor C_{C1} changes according to the storage data, and when low-level input data is input, the second capacitor C_{C2} is charged to a high voltage, and the third switching element 226 is turned on according to a charge sharing signal to connect the first capacitor C_{C1} to the second capacitor C_{C2}, causing an average value of charging voltages is charged in each capacitor.

The operation circuit 220 includes a first switching element 222 which is switched by a high-level bit of input data in a multi-bit format, has one terminal connected to the output node /Q of the storage unit 210, and has the other terminal connected to one terminal of the first capacitor C_{C1}, a second switching element 224 which is switched by a low-level bit of the input data in a multi-bit format, has one terminal connected to a power supply voltage, and has the other terminal connected to one terminal of the second capacitor C_{C2}, and the third switching element 226 which is connected between one terminal of the first capacitor C_{C1} and one terminal of the second capacitor C_{C2} and is switched by a charge sharing signal.

For more specific configuration, the operation circuit 220 includes the first switching element 222 which is switched by first input data IN_{P} and has one terminal connected to the output node /Q of the storage unit 210 and transmits the stored data to the other terminal Q_{C1}, the second switching element 224 which is switched by inverted second input data /IN_{N} or an inverted control signal /EV and has one terminal connected to a power supply voltage VDD and transmits the power supply voltage VDD to the other terminal Q_{C2}, the first capacitor C_{C1} which has one terminal connected to the other terminal Q_{C1} of the first switching element 222, the second capacitor C_{C2} which has one terminal connected to the other terminal Q_{C2} of the second switching element 224, and the third switching element 226 which is connected between one terminal of the first capacitor C_{C1} and one terminal of the second capacitor C_{C2} and is switched by a charge sharing signal CS. In addition, the other terminal of the first capacitor C_{C1} and the other terminal of the second capacitor C_{C2} are commonly connected to the output terminal BL_{c}.

Through the configuration, the operation circuit 220 performs a DAC operation for converting input data into an analog voltage and multiplication of the stored data and the input data. In addition, an NMOS transistor may be used as the first switching element 222, a PMOS transistor may be used as the second switching element 224, and a transmission gate may be used as the third switching element 226, but the present disclosure is not limited thereto and the first, second, and third switching elements 222, 224, and 226 may be modified to other elements.

A DAC function of the operation circuit 220 is performed as follows. That is, according to pulse signals applied to the first switching element 222 and the second switching element 224, a high level bit and a low level bit of multi-bit input data are respectively applied to the first switching element 222 and the second switching element 224. In addition, according to the charge sharing signal CS input in synchronization with an application time of a clock pulse signal, charging capacities of the first capacitor C_{C1} and the second capacitor C_{C2} are shared to output analog voltages corresponding to the input data. A specific operation process of each memory cell is described below.

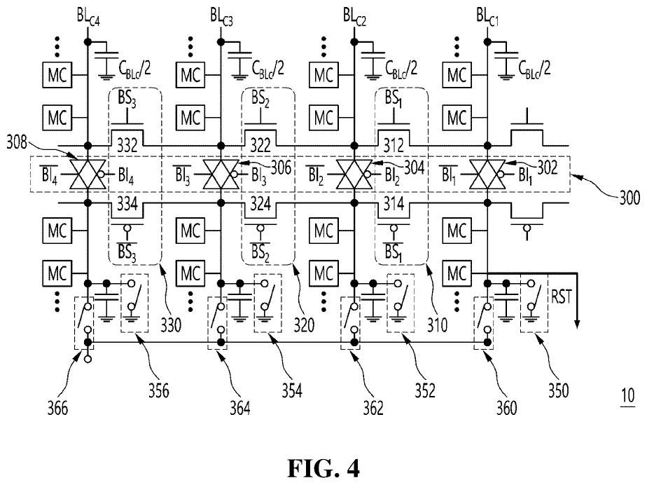

FIG. 4 illustrates a circuit serving as a shift adder and ADC among components of a memory device according to an embodiment of the present disclosure.

As illustrated in FIG. 4, a memory device 10 includes a plurality of bit lines BL_{c1} to BL_{cn} to which a plurality of memory cells MC are respectively connected, a separation switch 300 that selectively separates the plurality of bit lines BL_{c1} to BL_{cn} in response to a separation signal BIₙ for each bit line, first, second, and third sharing switches 310, 320, and 330 that selectively connect adjacent bit lines to each other in response to a charge sharing signal BSₙ, and ground switches 350 to 356 that ground respective bit lines to discharge the electric charges charged in capacitors.

As illustrated in FIG. 4, the plurality of memory cells MC constituting the memory cell array 100 are respectively coupled to the plurality of bit lines BL_{c} extending in a specific direction. Outputs of the plurality of memory cells MC are transmitted to the plurality of bit lines BL_{c}, which are charged as capacitances of the plurality of bit line BL_{c} in the form of electric charges. The capacitances of the plurality of bit line BL_{c} represent all capacitance components that the plurality of bit lines have and include parasitic capacitor components, and in FIG. 4, capacitors arc illustrated as an equivalent circuit concept of all the capacitance components. That is, in the present disclosure, separate capacitor elements are not combined, and instead, capacitances, which are formed inherently according to the formation of the plurality of bit lines BL_{c}, are used. The capacitances of the plurality of bit lines BL_{c} are proportional to lengths of the plurality of bit lines BL_{c}, and when the center of each of the plurality of bit lines BL_{c} is separated, the capacitance of each of the plurality of bit lines BL_{c} is reduced by half. In order to use this property, the present disclosure arranges the separation switch 300 in a central separation region of the plurality of bit lines BL_{c}. Meanwhile, a method of setting importance of a bit line may be performed in units of a group including the plurality of bit lines BL_{c}. For example, a bit line group is formed in the number of bit lines of 2, 3, 4, or more, and importances of the bit lines belonging to each group may be set differently. In addition, a bit line belonging to one end of a group may be in charge of the lowest bit, and a bit line belonging to the other end may be in charge of the highest bit. That is, as illustrated in FIG. 4, four bit lines may form one group, and a first bit line BL_{c1} may be in charge of the lowest bit, and a fourth bit line BL_{c4} may be in charge of the highest bit.

As illustrated in FIG. 4, when a central part of each bit line BL_{c} is separated, each bit line BL_{c} is separated into an upper bit line and a lower bit line based on the central separation region. In addition, the separation switch 300 is coupled to the central separation region of the plurality of bit lines BL_{c}. The upper bit line and the lower bit line may be selectively separated or coupled by an operation of the separation switch 300. According to this configuration, capacitance of each bit line may be adjusted to 1 or ½. Separation switches 302 to 308 may be implemented in the form of transfer gates that are turned on or off according to separation signals BI₁ to BI₄ but the present disclosure is not limited thereto and may also be implemented in the form of a general metal oxide semiconductor (MOS) device.

The first, second, and third sharing switches 310, 320, and 330 are respectively arranged between adjacent bit lines and separate or connect adjacent bit lines in response to charge sharing signals. In particular, when the first, second, and third sharing switches 310, 320, and 330 turn on, electric charges of capacitors of the plurality of bit lines BL, are shared such that an average value of the electric charges originally charged in the capacitors is charged to the capacitors. The first sharing switch 310 may include an upper-side first sharing switch 312 that connects an upper-side bit line of a first bit line BL_{c1} to an upper-side bit line of a second bit line BL_{c2} in response to a first charge sharing signal BS₁ and a lower-side first sharing switch 314 that connects a lower-side bit line of the first bit line BL_{c1} to a lower-side bit line of the second bit line BL_{c2} in response to an inverse first charge sharing signal /BS₁. In addition, the second sharing switch 320 may include an upper-side second sharing switch 322 that connects an upper-side bit line of the second bit line BL_{c2} to an upper-side bit line of a third bit line BL_{c3} in response to a second charge sharing signal BS₂ and a lower-side second sharing switch 324 that connects a lower-side bit line of the second bit line BL_{c2} to a lower-side bit line of the third bit line BL_{c3} in response to an inverse second charge sharing signal /BS₂. In addition, the third sharing switch 330 may include an upper-side third sharing switch 332 that connects an upper-side bit line of the third bit line BL_{c3} to an upper-side bit line of a fourth bit line BL_{c4} in response to a third charge sharing signal BS₃ and a lower-side third sharing switch 334 that connects a lower-side bit line of the third bit line BL_{c3} to a lower-side bit line of the fourth bit line BL_{c4} in response to an inverse third charge sharing signal /BS₃. In addition, an NMOS transistor may be used as a first switch of each sharing switch, and a PMOS transistor may be used as a second switch of each sharing switch, but the present disclosure is not limited thereto, and the first and second switch may be implemented by other types of switches.

In addition, the ground switches 350 to 356 may each be connected to one end of each of the plurality of bit lines for each bit line. For example, the ground switches 350 to 356 may each be connected to a lower bit line located at a lower end of a central separation region of each bit line, and may be used to discharge a capacitor of the lower bit line. According to an embodiment, the ground switch may be connected to only a bit line of which importance is desired to be set to the lowest among the plurality of bit lines 350 to 356. That is, although FIG. 4 illustrates that the ground switches 350 to 356 are connected to all bit lines, the ground switches 350 to 356 may be connected to only some bit lines according to an embodiment.

In addition, output switches 360 to 366, which transmit the electric charges charged in capacitors of the plurality of bit lines BL_{c1} to BL_{cn} to an external ADC circuit, may be further included. The output switches 360 to 366 are respectively connected to output terminals of a plurality of bit lines BL_{c1} to BL_{cn} and transmit the electric charges charged in capacitors of the plurality of bit lines BL_{c1} to BL_{cn} to an external ADC circuit. The output switches 360 to 366 may integrate operation results into units of two, three, four, or more bit lines and transmit the operation results to an external ADC circuit. For example, when the operation results are output by using the first bit line BL_{c1} to the fourth bit line BL_{c4} as the minimum unit, an output of the capacitor of the fourth bit line BL_{c4} may be transmitted to the ADC through the output switch 366. Meanwhile, although FIG. 4 illustrates that the output switches 360 to 366 are connected to all bit lines, a single output switch may be used in units of a plurality of bit lines.

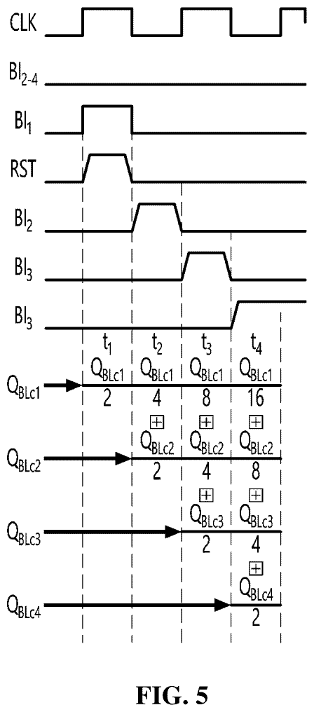

FIG. 5 is a waveform diagram illustrating a method of setting bit line importance of a memory device according to an embodiment of the present disclosure.

The method of setting bit line importance is described below with reference to FIGS. 4 and 5. First, output values of the memory cells are charged in capacitors of the respective bit lines BL_{c} before an operation. For example, when all the separation switches 302 to 308 of the respective bit lines turn on, outputs of the plurality of memory cells are applied to the capacitors of the respective bit lines BL_{c}. To this end, the separation signals BIₙ that turn on the separation switches 302 to 308 are applied respectively.

Next, during a first time period t1, electric charges charged in a capacitor of the first bit line BL_{c1} are discharged by half, such that the importance of the corresponding bit line is set to be lower than 1. More specifically, by turning on a first separation switch 302 coupled to the first bit line BL_{c1} and turning on the ground switch 350 coupled to a lower bit line of the first bit line BL_{c1}, the electric charges charged in a capacitor of the lower bit line of the first bit line BL_{c1} are discharged. The ground switches of the other bit lines are maintained in a turn-off state. In this case, because the first separation switch 302 is in a turn-off state, a capacitor of an upper bit line among all capacitors of the first bit line BL_{c1} is maintained in a charging state, and a capacitor of the lower bit line is discharged, such that only the electric charges corresponding to half of the initial electric charges Q_{BLc1} are in a charged in the capacitor. In this way, the importance of electric charges charged in the capacitor of the first bit line may be changed from 1 to ½ by an operation.

Next, during a second time period t2, all the separation switches 302 to 308 turn on, and accordingly, the central separation regions of the respective bit lines are connected. Then, the first sharing switch 310 connecting the first bit line BL_{c1} and the second bit line BL_{c2}, which are adjacent, to each other turns on, such that the electric charges charged in respective capacitors of the first bit line BL_{c1} and the second bit line BL_{c2} are shared. According to charge sharing, an average value of electric charge amount (½Q_{BLc1}) charged in the capacitor of the first bit line BL_{c1} and electric charge amount (Q_{BLc2}) charged in the capacitor of the second bit line BL_{c2} is charged in the capacitor of the first bit line BL_{c1} and the capacitor of the second bit line BL_{c2}. That is, electric charges corresponding to ¼Q_{BLc1}+½Q_{BLc2} are charged in the capacitor of the first bit line and the capacitor of the second bit line. In this way, importance of the electric charges charged in the capacitor of the first bit line may be set to ¼ by an operation, and importance of the electric charges charged in the capacitor of the second bit line may be set to ½ by the operation.

Next, during a third time period t3, the second sharing switch 320 connecting the second bit line BL_{c2} and the third bit line BL_{c3}, which are adjacent, to each other turns on such that the electric charges charged in each capacitor of the second bit line BL_{c2} and the third bit line BL_{c3} are shared. According to the charge sharing, an average value of the electric charge amount (¼Q_{BLc1}+½Q_{BLc2}) charged to the capacitor of the second bit line BL_{c2} and the electric charge amount (Q_{BLc3}) charged in the capacitor of the third bit line BL_{c3} is charged to the capacitor of the second bit line BL_{c2} and the capacitor of the third bit line BL_{c3}. That is, electric charges corresponding to ⅛Q_{BLc1}+¼Q_{BLc2}+½Q_{BLc3} are charged in the capacitor of the second bit line and the capacitor of the third bit line. In this way, the importance of the electric charges charged in the capacitor of the first bit line may be set to ⅛ by an operation, the importance of the electric charges charged in the capacitor of the second bit line may be set to ¼ by the operation, and the importance of the electric charges charged in the capacitor of the third bit line may be set to ½ by the operation.

Next, during a fourth time period t4, the third sharing switch 330 connecting the third bit line BL_{c3} and the fourth bit line BL_{c4}, which are adjacent, to each other turns on, such that the electric charges charged in the capacitors of the third bit line BL_{c3} and the fourth bit line BL_{c4} are shared. According to the charge sharing, an average value of the electric charge amount (⅛Q_{BLc1}+¼Q_{BLc2}+½Q_{BLc3}) charged in the capacitor of the third bit line BL_{c3} and the electric charge amount (Q_{BLc4}) charged in the capacitor of the fourth bit line BL_{c4} is charged in the capacitor of the third bit line BL_{c3} and the capacitor of the fourth bit line BL_{c4}. That is, the electric charges corresponding to 1/16Q_{BLc1}+⅛Q_{BLc2}+¼Q_{BLc3}+½Q_{BLc4} are charged in the capacitor of the third bit line and the capacitor of the fourth bit line. In this way, the importance of the electric charges charged in the capacitor of the first bit line may be set to 1/16 by an operation, the importance of the electric charges charged in the capacitor of the second bit line may be set to ⅛ by the operation, the importance of the electric charges charged in the capacitor of the third bit line may be set to ¼ by the operation, and the importance of the electric charges charged in the capacitor of the fourth bit line may be set to ½ by the operation.

In addition, the output switches 360, 362, 364, and 366 may be turned on as needed for each section step, such that the electric charges charged in the capacitor of each bit line may be output to an ADC. For example, when performing an operation in units of two bit lines, the output switch 362 connected to the second bit line BL_{c2} may be turned on after an operation of the second time period t2 such that the electric charges charged in the capacitor of the corresponding bit line may be output. In addition, when performing an operation in units of three bit lines, the output switch 364 connected to the third bit line BL_{c3} may be turned on after an operation of the third time period t3 such that the electric charges charged in the capacitor of the corresponding bit line may be output. In addition, when performing an operation in units of four bit lines, the output switch 366 connected to the fourth bit line BL_{c4} may be turned on after an operation of the fourth time period t4 such that the electric charges charged in the capacitor of the corresponding bit line may be output.

In this way, the present disclosure may set the importance of each bit line for each capacitor by using a circuit built in the memory cell array 100 and output the importance to an external ADC.

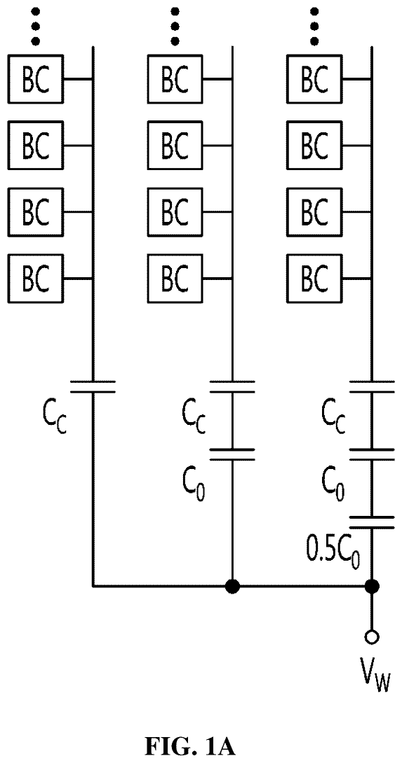

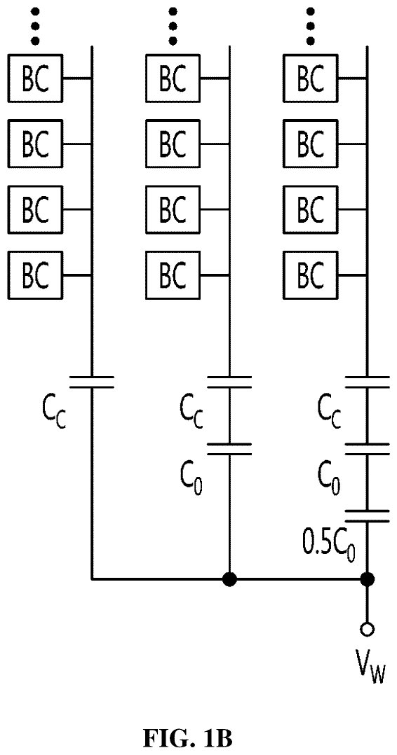

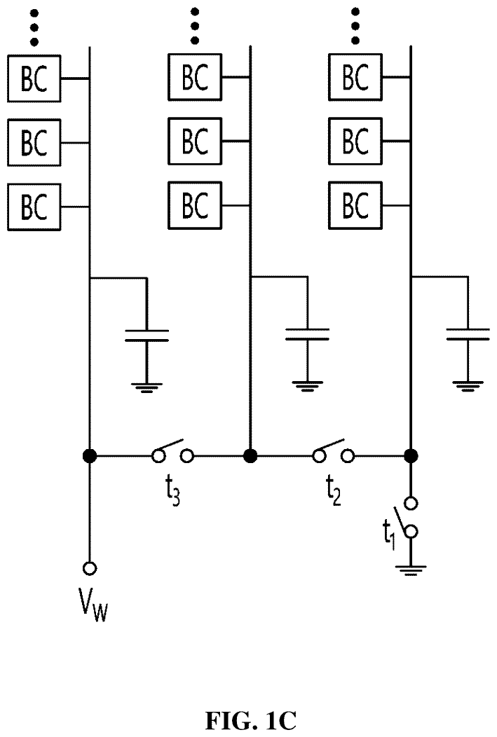

That is, unlike the general shift-add circuit of FIG. 1, the present disclosure may implement a shift-add circuit in a form built in the memory cell array 100, and thus, an area of the memory device 10 may be greatly reduced. In addition, because an output of a capacitor of each bit line is shifted and added within the memory cell array 100, there is also an advantage in that an ADC circuit for converting a corresponding output into a digital signal may be minimized. That is, because the shift and addition operation is performed in a predetermined bit unit to output an operation result to an ADC circuit, the number of ADC circuits may be significantly reduced compared to a case where an output is provided to the ADC circuit for each bit line.

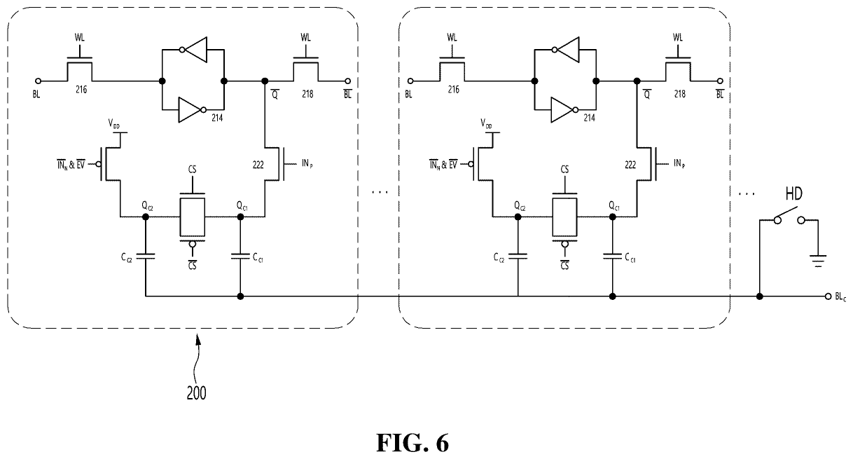

FIG. 6 illustrates a configuration in which a plurality of memory cells are combined according to an embodiment of the present disclosure.

As illustrated in FIG. 6, a plurality of memory cells 200 may be connected to one row, and output terminals BLc of the operation circuits 220 of respective memory cells 200 are commonly connected to each other. In addition, a holding switching element that is activated by a hold signal HD and selectively connects the output terminal BLc to a ground may be combined to the memory cell 200.

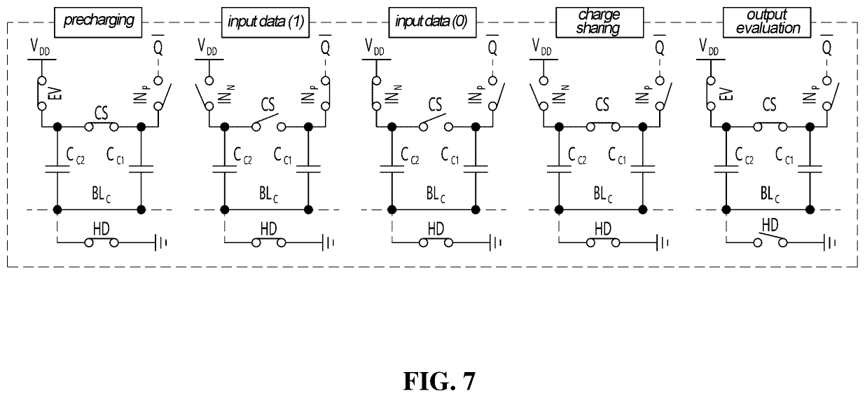

FIGS. 7, 8, 9, and 10 are diagrams illustrating an operation of a memory cell according to an embodiment of the present disclosure.

For the sake simplicity of description, FIG. 7 illustrates only an operation of the operation circuit 220 in the memory cell 200.

First, in a precharge step, the power supply voltage VDD is applied to the first capacitor C_{C1} and the second capacitor C_{C2}. To this end, a control signal EV is applied to the second switching element 224 to turn on the second switching element 224, and the charge sharing signal CS is also applied to turn on the third switching element 226. Accordingly, the power supply voltage VDD is applied to the first capacitor C_{C1} and the second capacitor C_{C2}, such that the first capacitor C_{C1} and the second capacitor C_{C2} are charged to high voltages.

Next, a data application mode for applying the input data and the storage data to each capacitor is performed. Among the input data in a multi-bit format, a high level bit is applied as first input data IN_{P}, and a low level bit is applied as second input data IN_{N}. To this end, the first input data IN_{P} and the inverted second input data /IN_{N} are respectively applied to a gate of the first switching element 222 and a gate of the second switching element 224. In addition, when the high level bit among the input data is received, the first input data IN_{P} is set to a high level 1, and when the low level bit is received, the second input data IN_{N} is set to a low level 0. In this case, the first switching element 222 is an NMOS transistor, and the second switching element 224 is a PMOS transistor, and accordingly, inverted second input data/IN_{N} is applied to a gate of the second switching element 224. In addition, while the input data is applied to each switching element, the charge sharing signal CS is blocked, and accordingly, the input data is separately applied to the respective capacitors.

thereafter, in a charge sharing mode, input data application is blocked, and the charge sharing signal CS is applied for a certain period of time to cause electric charges to be shared with each capacitor. In addition, when the input data is n-bit data, input data application and charge sharing are repeatedly performed by n times.

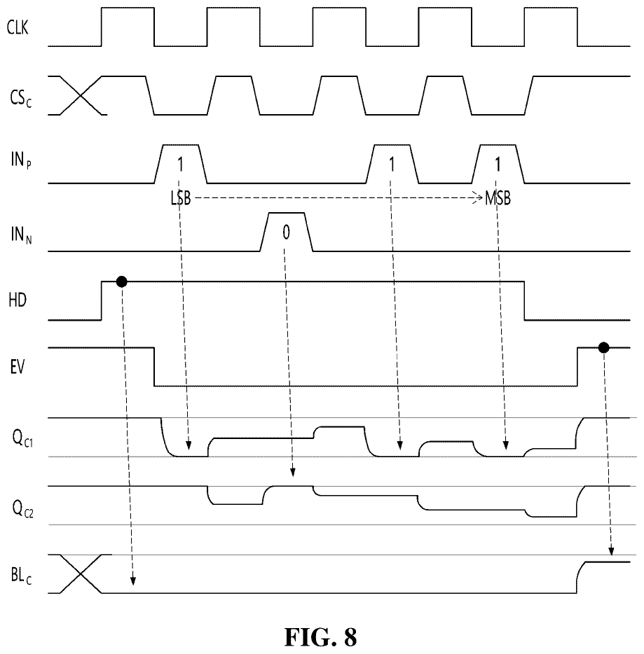

FIG. 8 illustrates an example where the input data is ‘1101’. A least significant bit (LSB) is input first, and after respective pieces of input data are applied sequentially, a most significant bit (MSB) is input last.

First, as ‘1’ is input as the LSB, the first input data IN_{P} of a high level is applied to the first

switching element 222, and the second input data IN_{N} of a low level is applied to the second switching element 224. As the first switching element 222 is turned on and the second switching element 224 is turned off, a charging state of the first capacitor C_{C1} charged to a high voltage in the precharge step is changed by the storage data stored in the storage unit 210.

That is, when the storage data ‘1’ is stored in the storage unit 210 (an output of the first inverter 212 is 1), the output node /Q decreases to a low level GND, and accordingly, the first capacitor C_{C1} is discharged, as illustrated in FIG. 8. In contrast to this, when the storage data ‘0’ is stored in the storage unit 210 (an output of the second inverter 214 is 1), the output node /Q increases to a high level VDD, and accordingly, the first capacitor C_{C1} may maintain a high voltage charging state. In addition, after the LSB of ‘1’ is input, when the charge sharing signal CS is applied, the first and second switching elements 222 and 224 are turned off, and each of the first capacitor C_{C1} and the second capacitor C_{C2} has an average value (0.5 VDD) of charged electric charges due to charge sharing. As illustrated in FIG. 8, a voltage charging state changes to an average state of the discharged first capacitor C_{C1} and the high-voltage charged second capacitor C_{C2}.

Next, as ‘0’ is input as a third bit, the first input data IN_{P} at a low level is applied to the first switching element 222, and the second input data IN_{N} at a high level is applied to the second switching element 224. Because the second input data IN_{N} at a high level is inverted and applied to the second switching element 224, the second switching element 224 is turned on and the first switching element 222 is turned off. Accordingly, the power supply voltage VDD is applied to the second capacitor C_{C2}, and thereby, the second capacitor C_{C2} is charged to a high level, and the first capacitor C_{C1} maintains the previous state. Thereafter, when the charge sharing signal CS is applied, the first and second switching elements 222 and 224 are turned off, and each of the first capacitor C_{C1} and the second capacitor C_{C2} has an average value of the electric charges charged by the charge sharing. As ‘0’ is applied as the third bit and the second capacitor C_{C2} is charged to a high level, it can be seen that a charging voltage (0.75 VDD) of each of the first capacitor C_{C1} and the second capacitor C_{C2} increases compared to the charging voltage at the time of the previous charge sharing.

Next, as ‘1’ is input as the second bit, the first input data IN_{P} at a high level is applied to the first switching element 222, and the second input data IN_{N} at a low level is applied to the second switching element 224. As described above, as the first switching element 222 is turned on, a charging state of the first capacitor C_{C1} changes according to the storage data stored in the storage unit 210. Thereafter, when the charge sharing signal CS is applied, each of the first capacitor C_{C1} and the second capacitor C_{C2} has an average value of the charged electric charges.

Next, as ‘1’ is input as the MSB, the first input data IN_{P} at a high level is applied to the first switching element 222, and the second input data IN_{N} at a low level is applied to the second switching element 224. As the first switching element 222 is turned on, a charging state of the first capacitor C_{C1} is changed by the storage data stored in the storage unit 210. Thereafter, when the charge sharing signal CS is applied, each of the first capacitor C_{C1} and the second capacitor C_{C2} has an average value of the charged electric charges, and the average value is determined as a final charge voltage Visional.

Finally, in an output evaluation step, the inverted control signal /EV is applied to the second switching element 224, the first switching element 222 is maintained in a turn-off state, and a holding signal HD applied to the holding switching element is blocked. Accordingly, a voltage of one terminal of the second capacitor C_{C2} increases to a power supply voltage level, and the other terminal of the second capacitor C_{C2}, that is, the output terminal BLc, outputs an evaluation voltage. In this case, the evaluation voltage becomes VDD−Vcs,final (final charge voltage) by capacitor coupling. That is, immediately before an output evaluation step, each of one terminal of the first capacitor C_{C1} and one terminal of the second capacitor C_{C2} has the average value Vcs,final of the charged electric charges, and as a power supply voltage is applied to one terminal of the first capacitor C_{C1} and one terminal of the second capacitor C_{C2} during the output evaluation step, each of voltages of the other terminal of the first capacitor C_{C1} and the other terminal of the second capacitor C_{C2} is set to VDD−Vcs,final (final charge voltage).

In this way, the operation circuit 220 adjusts voltages of the output terminals of the first and second capacitors C_{C1} and C_{C2} according to the input data input through gates of the first and second switching elements 222 and 224 and the storage data stored in the storage unit 210. That is, the operation circuit 220 may perform a NAND operation on the input data and the storage data. In addition, it can be seen that the operation circuit 220 also performs a DAC function that converts digital input data input through gates of the first and second switching elements 222 and 224 into an analog voltage through charging voltages of the first and second capacitors C_{C1} and C_{C2}.

In the conventional technology, a voltage is applied to a source or drain of a switching element to transmit an analog voltage value to each capacitor, but in the present disclosure, input data is applied as a gate signal of a switching element, and thus, the present disclosure is effective for small and fast signal transmission.

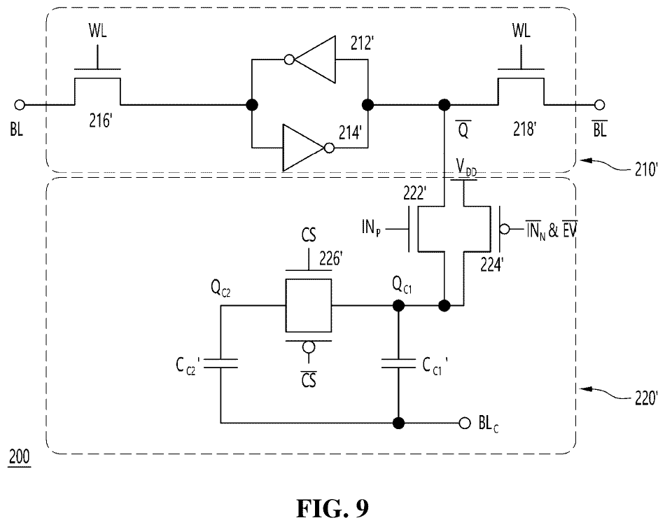

FIG. 9 illustrates a detailed configuration of a memory cell according to another embodiment of the present disclosure.

A configuration of a storage unit 210′ is the same as the storage unit 210 of FIG. 3, and accordingly, detailed description thereof is omitted.

A configuration of the operation circuit 220′ also generally corresponds to the operation circuit 220 of FIG. 3, but there is a difference in a configuration of the second switching element 224′. The second switching element 224′ has a structure in which the other terminal of the second switching element 224′ is connected to one terminal of a first capacitor C_{C1}′.

More specifically, the operation circuit 220′ includes a first switching element 222′ that is switched by first input data INp and has one terminal connected to an output node /Q of the storage unit 210′ and transmits the stored data to the other terminal Q_{C1}, the second switching element 224′ that is switched by second input data IN_{N} or a control signal EV and has one terminal connected to a power supply voltage VDD and transmits the power supply voltage VDD to the other terminal Q_{C1}, the first capacitor C_{C1}′ that has one terminal connected to the other terminal Q_{C1} of the first switching element 222′ and the second switching element 224′ and has the other terminal connected to an output terminal BLc, a second capacitor C_{C2}′ that has the other terminal connected to the output terminal BLc, and a third switching element 226′ connected between one terminal of the first capacitor C_{C1}′ and one terminal of the second capacitor C_{C2}′ and switched by a charge sharing signal CS.

A detailed operation thereof also generally corresponds to the operation of FIG. 3.

First, in a precharge step, initialization for applying the power supply voltage VDD to the first capacitor C_{C1}′ and the second capacitor C_{C2}′ is performed. To this end, the control signal EV is applied to the second switching element 224 to turn on the second switching element 224′, and the charge sharing signal CS is also applied to turn on the third switching element 226′. Accordingly, the power supply voltage VDD is applied to the first capacitor C_{C1} and the second capacitor C_{C2}.

Next, in a data application mode, the first input data IN_{P} and the inverted second input data /IN_{N} are respectively applied to gates of the first switching element 222′ and the second switching element 224′. Then, while the input data is applied to the first and second switching elements 222′ and 224′, the charge sharing signal CS is blocked such that the input data is separately applied to the first and second capacitors C_{C1} and C_{C2}. Thereafter, the application of the input data is blocked, and the charge sharing signal CS is applied for a certain period of time such that electric charges are shared between respective capacitors.

Meanwhile, when the first input data IN_{P} is at a high level, the first switching element 222′ is turned on, and accordingly, storage data stored in the storage unit 210 may be transmitted to the capacitor through the output node /Q and the first switching element 222′.

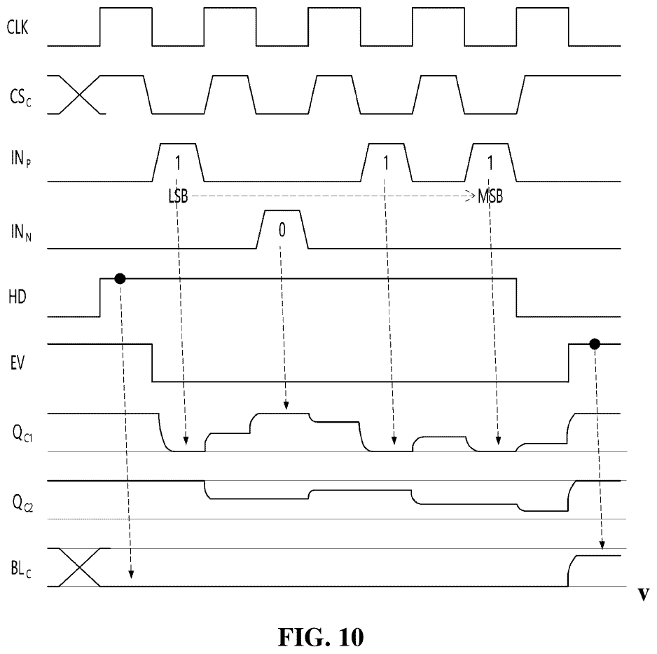

Referring to FIG. 10 for a detailed operation, when ‘1’ is input as an LSB, the first switching element 222′ is turned on and the second switching element 224′ is turned off, and accordingly, a charging state of the first capacitor C_{C1}′ charged to a high voltage during a precharge step is changed by the storage data stored in the storage unit 210. That is, when the storage data ‘1’ is stored in the storage unit 210, the output node /Q decreases to a low level GND, and accordingly, the first capacitor C_{C1}′ is discharged. In contrast to this, when the storage data ‘0’ is stored in the storage unit 210, the output node /Q increases to a high level VDD, and accordingly, the first capacitor C_{C1}′ may maintain a high-voltage charging state. In addition, when the charge sharing signal CS is applied after an LSB ‘1’ is input, the first and second switching elements 222′ and 224′ are turned off, and each of the first capacitor C_{C1}′ and the second capacitor C_{C2}′ has an average value (0.5 VDD) of electric charges charged by the charge sharing.

Next, when ‘0’ is input as a third bit, the second switching element 224′ is turned on, and the first switching element 222′ is turned off. Accordingly, the power supply voltage VDD is applied to the first capacitor C_{C1}′, such that the first capacitor C_{C1}′ is charged to a high level, and the second capacitor C_{C2}′ maintains a previous state. Unlike the embodiments of FIGS. 3 and 6, when the input data is ‘0’, the first capacitor C_{C1}′ is charged to a high level. Thereafter, the first capacitor C_{C1}′ and the second capacitor C_{C2}′ are each charged to an average value by the charge sharing signal CS.

Next, as ‘1’ is input as a second bit, the first switching element 222′ is turned on and the second switching element 224′ is turned off, and accordingly, a charging state of the first capacitor CC1′is changed by the storage data stored in the storage unit 210. Thereafter, the first capacitor C_{C1}′ and the second capacitor C_{C2}′ are each charged to an average value by the charge sharing signal CS.

Next, as ‘1’ is input as an MSB, the first switching element 222′ is turned on and the second switching element 224′ is turned off, and accordingly, a charging state of the first capacitor C_{C1}′ is changed by the storage data stored in the storage unit 210. Thereafter, the first capacitor C_{C1}′ and the second capacitor C_{C2}′ are each charged to an average value by the charge sharing signal CS again, and the average value is determined as the final charge voltage Visional.

Finally, in an output evaluation step, the inverted control signal /EV is applied to the second switching element 224′, the first switching element 222′ maintains a turn-off state, the holding signal HD applied to a holding switching element is blocked. Accordingly, a voltage of one terminal of the first capacitor C_{C1}′ increases to the power supply voltage level VDD, and a voltage of the other terminal of the first capacitor C_{C1}′, that is, the output terminal BL_{c}, becomes VDD−Vcs,final (final charge voltage) by capacitor coupling.

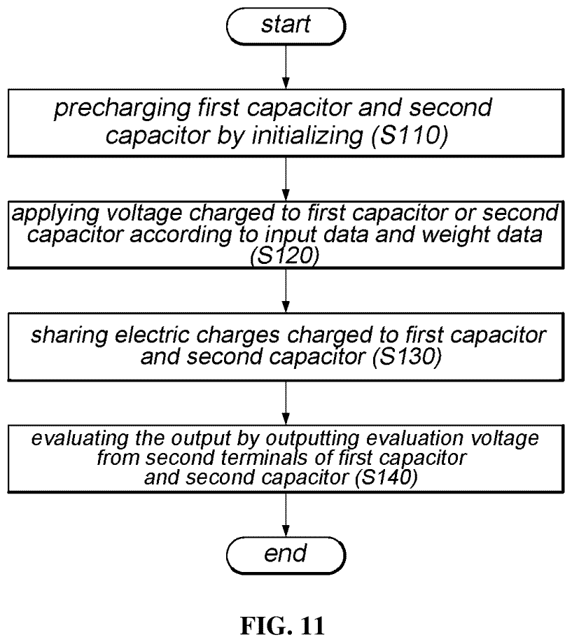

FIG. 11 is a flowchart illustrating an operating method of a memory cell included in a memory device, according to an embodiment of the present disclosure.

First, a precharge step of charging a first capacitor and a second capacitor with a power supply voltage is performed (S110).

Next, a data application step is performed (S120) to adjust a voltage charged to the first capacitor or the second capacitor according to input data and storage data of the storage unit 210.

The data application step may be performed as in the embodiment of FIG. 3. That is, when a high-level bit of the input data is input, the storage data is applied to the first capacitor such that a charging voltage of the first capacitor is adjusted by the storage data, and when a low-level bit is input, the second capacitor is charged with the power supply voltage.

In contrast to this, the data application step may be performed as in the embodiment of FIG. 10. That is, when a high-level bit of the input data is input, the storage data is applied to the first capacitor such that a charging voltage of the first capacitor is adjusted by the storage data, and when a low-level bit is input, the first capacitor is charged with the power supply voltage.

Next, after the data application step, a charge sharing step (S130) is performed to share electric charges charged to the first capacitor and the second capacitor.

Next, after the charge application step, the power supply voltage is applied to one terminal of the first capacitor and one terminal of the second capacitor such that an evaluation voltage is output to the other terminal of the first capacitor and the other terminal of the second capacitor (S140).

Because a level of the evaluation voltage changes depending on a result of multiplication of the input data and weight data, the multiplication of the input data and the weight data may be determined based on a level measurement result of the evaluation voltage.

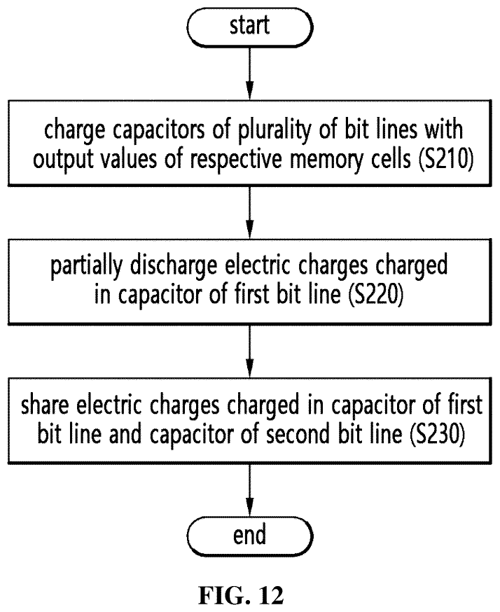

FIG. 12 is a flowchart illustrating a method of setting importance of a bit line of a memory device, according to an embodiment of the present disclosure.

First, an output value of each memory cell is charged to a capacitor of each bit line, within a bit line group including a predetermined number of bit lines (S210).

Next, some of the electric charges charged in a capacitor of a first bit line among bit line groups are discharged (S220). As in the operation of the first time period t1 of FIG. 5, the separation switch 302 and the ground switch 350 are turned on to discharge the electric charges charged in the capacitor of the first bit line by half.

Next, the electric charges of the capacitor of the first bit line and the capacitor of the second bit line, which are adjacent to each other, are shared, such that the electric charges charged in a partially discharged capacitor of the first bit line and the electric charges charged in the capacitor of the second bit line are shared (S230). As in the operation of the second time period t2 of FIG. 5, the sharing switch 310 may be turned on to share the electric charges charged in the capacitor of the first bit line and the capacitor of the second bit line. According to this operation, the capacitor of the first bit line and the capacitor of the second bit line may be charged with electric charges corresponding to the sum of ½ of an initial charge amount in the capacitor of the second bit line and ¼ of an initial charge amount in capacitor of the first bit line.

Next, a step of sharing the electric charges in the capacitor of the second bit line and the capacitor of the third bit line, which are adjacent to each other, may be further included to share the electric charges charged in the capacitor of the second bit line and the electric charges charged in the capacitor of the third bit line. As in the operation of the third time period t3 of FIG. 5, the sharing switch 320 may be turned on to share the electric charges charged in the capacitor of the second bit line and the capacitor of the third bit line. According to this operation, the capacitor of the second bit line and the capacitor of the third bit line may be charged with electric charges corresponding to the sum of ½ of the initial electric charge amount of the capacitor of the third bit line, ¼ of the initial electric charge amount of the capacitor of the second bit line, and ⅛ of the initial electric charge amount of the capacitor of the first bit line.

Next, a step of sharing the electric charges in the capacitor of the third bit line and the capacitor of the fourth bit line, which are adjacent to each other, may be further included to share the electric charges charged in the capacitor of the third bit line and the electric charges charged in the capacitor of the fourth bit line. As in the operation of the fourth time period t4 of FIG. 5, the sharing switch 330 may be turned on to share the electric charges charged in the capacitor of the third bit line and the capacitor of the fourth bit line. According to this operation, the capacitor of the third bit line and the capacitor of the fourth bit line may be charged with electric charges corresponding to the sum of ½ of the initial electric charge amount of the capacitor of the fourth bit line, ¼ of the initial electric charge amount of the capacitor of the third bit line, and ⅛ of the initial electric charge amount of the capacitor of the second bit line, and 1/16 of the initial electric charge amount of the capacitor of the first bit line.

A method according to an embodiment of the present disclosure may be performed in the form of a recording medium including instructions executable by a computer, such as a program module executed by a computer. A computer readable medium may be any available medium that may be accessed by a computer and includes both volatile and nonvolatile media, removable and non-removable media. Also, the computer readable medium may include a computer storage medium. A computer storage medium includes both volatile and nonvolatile media and removable and non-removable media implemented by any method or technology for storing information, such as computer readable instructions, data structures, program modules or other data.

In addition, although the method and system of the present disclosure are described with respect to specific embodiments, some or all of components or operations thereof may be implemented by using a computer system having a general-purpose hardware architecture.

The above description of the present disclosure is intended to be illustrative, and those skilled in the art will appreciate that the present disclosure may be readily modified in other specific forms without changing the technical idea or essential characteristics of the present disclosure. Therefore, the embodiments described above should be understood as illustrative in all respects and not limiting. For example, each component described in a single type may be implemented in a distributed manner, and likewise, components described in a distributed manner may be implemented in a combined form.

The scope of the present application is indicated by the claims described below rather than the detailed description above, and all changes or modified forms derived from the meaning, scope of the claims, and their equivalent concepts should be interpreted as being included in the scope of the present application.

What is claimed is:

1. A memory device comprising:
a plurality of memory cells;
a plurality of bit lines respectively connected to the plurality of memory cells;
a plurality of separation switches, each being arranged in a central separation region of each of the plurality of bit lines for each bit line and separating the central separation region of each of the plurality of bit lines in response to a separation signal or connecting separated central separation regions to each other in response to the separation signal;
a plurality of sharing switches, each being arranged between adjacent bit lines and separating the adjacent bit lines from each other or connecting the adjacent bit lines to each other in response to a charge sharing signal; and
at least one ground switch connected to one end portion of each of the plurality of bit lines for each bit line and selectively grounding each of the plurality of bit lines.

2. The memory device of claim 1, wherein
output values of the plurality of memory cells are stored in capacitors of the plurality of bit lines, and
electric charges charged in the capacitors of the plurality of bit lines are controlled according to operations of the plurality of separation switches, the plurality of sharing switches, or the plurality of ground switches.

3. The memory device of claim 1, wherein
output values of the plurality of memory cells charged in capacitors of the plurality of bit lines are output by being combined with importances set differently for each bit line, according to operations of the plurality of separation switches, the plurality of sharing switches, and the plurality of ground switches.

4. The memory device of claim 1, further comprising:
at least one output switch connected to one end portion of each of the plurality of bit lines for each bit line and transmitting electric charges stored in capacitors of the plurality of bit lines to an analog-to-digital converter (ADC).

5. The memory device of claim 1, wherein
output values of the plurality of memory cells charged in capacitors of the plurality of bit lines are output by being combined with importances set differently for each bit line, according to operations of the plurality of separation switches, the plurality of sharing switches, and the plurality of ground switches, and
importance of electric charges charged in a capacitor of a first bit line is set differently from importance of electric charges charged in a capacitor of a second bit line by combining an operation of discharging a half of the electric charges charged in the capacitor of the first bit line through one of the plurality of ground switches and an operation of sharing the electric charges in the capacitor of the first bit line and the electric charges in the capacitor of the second bit line through some of the plurality of sharing switches.

6. The memory device of claim 1, wherein,
in a state where output values of the plurality of memory cells are charged in a capacitor of a first bit line and a capacitor of a second bit line, the separation switch of the first bit line is turned off to divide electric charges charged in the capacitor of the first bit line,
a ground switch coupled to the first bit line is turned on to discharge a half of the electric charge charged in the capacitor of the first bit line, and
a first sharing switch connected to the first bit line and the second bit line is turned on to cause an average value of the electric charges charged in the capacitor of the first bit line and electric charges charged in the capacitor of the second bit line is charged in the capacitor of the first bit line and the capacitor of the second bit line.

7. The memory device of claim 6, wherein
according to the operation, the capacitor of the first bit line and the capacitor of the second bit line are respectively charged with electric charges corresponding to a sum of a half of an initial electric charge amount in the capacitor of the second bit line and a quarter of an initial electric charge amount in the capacitor of the first bit line.

8. The memory device of claim 1, wherein,
in a state where output values of the plurality of memory cells are respectively charged in a capacitor of a first bit line, a capacitor of a second bit line, and a capacitor of a third bit line, the separation switch connected to the first bit line is turned off to divide electric charges charged in the capacitor of the first bit line,
the ground switch connected to the first bit line is turned on to discharge a half of the electric charges charged in the capacitor of the first bit line,
an average value of electric charges charged in the capacitor of the second bit line and the electric charges charged in the capacitor of the first bit line are charged in the capacitor of the first bit line and the capacitor of the second bit line by turning on a first sharing switch connected to the first bit line and the second bit line, and
an average value of the electric charges charged in the capacitor of the second bit line and electric charges charged in a capacitor of a third bit line are charged in the capacitor of the second bit line and the capacitor of the third bit line by turning on a second sharing switch connected to the second bit line and the third bit line.

9. The memory device of claim 8, wherein
according to the operation, the capacitor of the second bit line and the capacitor of the third bit line are respectively charged with electric charges corresponding to a sum of a half of an initial electric charge amount in the capacitor of the third bit line, a quarter of an initial electric charge amount in the capacitor of the second bit line, and ⅛ of an initial electric charge amount in the capacitor of the first bit line.

10. The memory device of claim 1, wherein,
in a state where output values of the plurality of memory cells are respectively charged in a capacitor of a first bit line, a capacitor of a second bit line, a capacitor of a third bit line, and a capacitor of a fourth bit line, the separation switch connected to the first bit line is turned off to divide electric charges charged in the capacitor of the first bit line,
the ground switch connected to the first bit line is turned on to discharge a half of the electric charges charged in the capacitor of the first bit line,
an average value of electric charges charged in the capacitor of the second bit line and the electric charges charged in the capacitor of the first bit line are charged in the capacitor of the first bit line and the capacitor of the second bit line by turning on a first sharing switch connected to the first bit line and the second bit line,
an average value of the electric charges charged in the capacitor of the second bit line and electric charges charged in a capacitor of a third bit line are charged in the capacitor of the second bit line and the capacitor of the third bit line by turning on a second sharing switch connected to the second bit line and the third bit line, and
an average value of the electric charges charged in the capacitor of the third bit line and electric charges charged in a capacitor of a fourth bit line are charged in the capacitor of the third bit line and the capacitor of the fourth bit line by turning on a third sharing switch connected to the third bit line and the fourth bit line.

11. The memory device of claim 10, wherein
according to the operation, the capacitor of the third bit line and the capacitor of the fourth bit line are respectively charged with electric charges corresponding to a sum of a half of an initial electric charge amount in the capacitor of the fourth bit line, a quarter of an initial electric charge amount in the capacitor of the third bit line, ⅛ of an initial electric charge amount in the capacitor of the third bit line, and 1/16 of an initial electric charge amount in the capacitor of the fourth bit line.

12. An operating method of a memory device that sets importance of each bit line and includes a plurality of memory cells and a plurality of bit lines respectively connected to the plurality of memory cells, the operating method comprising:
(a) charging capacitors of the plurality of bit lines with output values of the plurality of memory cell, within a bit line group including a predetermined number of bit lines;
(b) partially discharging electric charges charged in a capacitor of a first bit line in the bit line group; and
(c) sharing the electric charges charged in the capacitor of the first bit line which is partially discharged and electric charges charged in a capacitor of a second bit line by sharing electric charges in the capacitor of the first bit line and the capacitor of the second bit line which are adjacent to each other.

13. The operating method of claim 12, further comprising:
(d) sharing the electric charges charged in the capacitor of the second bit line and electric charges charged in a capacitor of a third bit line by sharing the electric charges in the capacitor of the second bit line and the capacitor of the third bit line which are adjacent to each other.

14. The operating method of claim 13, further comprising:
(e) sharing the electric charges charged in the capacitor of the third bit line and electric charges charged in a capacitor of a fourth bit line by sharing the electric charges in the capacitor of the third bit line and the capacitor of the fourth bit line which are adjacent to each other.

15. The operating method of claim 12, wherein, in (b), the first bit line is separated through a separation switch arranged in a central separation region of the first bit line, and a bit line below the separation switch of the first bit line is grounded to discharge a half of the electric charges charged in the capacitor of the first bit line.

16. The operating method of claim 12, wherein, in (c),
the first bit line is connected to the second bit line through a sharing switch arranged between the first bit line and the second bit line, and according to the sharing, the capacitor of the first bit line and the capacitor of the second bit line are each charged with electric charges corresponding to a sum of a half of an initial electric charge amount in the capacitor of the second bit line and a quarter of an initial electric charge amount in the capacitor of the first bit line.

17. The operating method of claim 13, wherein, in (d),
the second bit line is connected to the third bit line through a sharing switch arranged between the second bit line and the third bit line, and according to the sharing, the capacitor of the second bit line and the capacitor of the third bit line are each charged with electric charges corresponding to a sum of a half of an initial electric charge amount in the capacitor of the third bit line, a quarter of an initial electric charge amount in the capacitor of the second bit line, and ⅛ of an initial electric charge amount in the capacitor of the first bit line.

18. The operating method of claim 14, wherein, in (e),
the third bit line is connected to the fourth bit line through a sharing switch arranged between the third bit line and the fourth bit line, and according to the sharing, the capacitor of the third bit line and the capacitor of the fourth bit line are each charged with electric charges corresponding to a sum of a half of an initial electric charge amount in the capacitor of the fourth bit line, a quarter of an initial electric charge amount in the capacitor of the third bit line, ⅛ of an initial electric charge amount in the capacitor of the second bit line, and 1/16 of an initial electric charge amount in the capacitor of the first bit line.
